(19) United States
(12) Patent Application Publication
(10) Pub. No.: US 2007/0002637 A1
(43) Pub. Date: Jan. 4, 2007

(54) Semiconductor memory device

(75) Inventors: Ji-Eun Jang, Ichon-shi (KR); Kee-Teok Park, Ichon-shi (KR)

Correspondence Address: MCDERMOTT WILL & EMERY LLP, 600 13TH STREET, N.W., WASHINGTON, DC, 20005-3096, US

(73) Assignee: Hynix Semiconductor Inc.

(21) Appl. No.: 11/304,819

(22) Filed: Dec. 16, 2005

(30) Foreign Application Priority Data
Jun. 30, 2005 (KR) 2005-0058715

(51) Int. Cl. G11C 7/10

(52) U.S. Cl. 365/189.05

(57) ABSTRACT

A semiconductor memory device includes: a command input buffer unit for buffering a command signal and for generating a detection signal in response to a write command; a data input enable control unit for generating a data input enable signal in response to the detection signal; a data input buffer unit for transferring a data in response to the data input enable signal; a command decoder for decoding the command signal to thereby generate a decoded signal; and a core region for storing the data transferred by the data input buffer unit in response to the decoded signal.

### FIELD OF INVENTION

The present invention relates to a semiconductor memory device; and, more particularly, to a semiconductor memory device capable of processing data at a high speed.

### DESCRIPTION OF PRIOR ART

An operation of a semiconductor memory device can be roughly classified into two operations, i.e., a read operation for reading data and a write operation for storing data. At the read operation, a data stored in a memory cell selected by a corresponding address is outputted. At the write operation, a data is stored into a memory cell selected by a corresponding address.

Recently, various technologies have been developed in order to improve an operational speed of the semiconductor memory device.

Firstly, an input/output operation of a plurality of data is performed through a parallel data path at a single read/write operation.

Secondly, when an address for a single read/write operation is inputted, data stored in memory cells corresponding to consecutive addresses from the inputted address are sequentially outputted through a single data path, or data are sequentially stored into the memory cells corresponding to the consecutive addresses from the inputted address through the single data path.

Thirdly, a read/write operation is performed in synchronization with a reference clock. That is, the read/write operation is performed at a rising edge or a falling edge of the reference clock, or the read/write operation is performed at both a rising edge and a falling edge of the reference clock. In this case, a command is also inputted to the semiconductor memory device in synchronization with the reference clock. Herein, a column address strobe (CAS) latency is defined as the number of clock cycles which is a required waiting time for outputting data since a read command is inputted. Herein, the command is inputted as a combination of command signals, i.e., a chip selection bar signal csb, a row address strobe bar signal rasb, a column address strobe bar signal casb and a write enable bar signal web. The semiconductor memory device decodes the command to thereby perform a corresponding operation.

Meanwhile, in case of a double data rate (DDR) memory device which performs the read/write operation in synchronization with both a rising edge and a falling edge of the reference clock, a data input/output timing should be very accurate. Therefore, for improving accuracy of the data input/output timing, a data strobe signal synchronized with the data input/output timing is used.

That is, when data are inputted or outputted, the data strobe signal clocks according to the number of the inputted or outputted data, and the semiconductor memory device performs the read/write operation according to the data strobe signal.

FIG. 1 is a block diagram showing a conventional semiconductor memory device.

As shown, the conventional semiconductor memory device includes a command input buffer unit 10, a command delay unit 20, a command decoder 30, a core region 40, a data input enable control unit 50 and a data input buffer unit 60.

The command input buffer unit 10 buffers a plurality of command signals, i.e., a chip selection bar signal csb, a row address strobe bar signal rasb, a column address strobe bar signal casb and a write enable bar signal web. The command delay unit 20 delays the buffered command signals and the command decoder 30 decodes the delayed command signals to thereby generate a write operation signal wtp6.

The data input enable control unit 50 generates a data input enable signal en_dinds in response to the write operation signal wtp6. The data input buffer unit 60 transfers a data to the core region 40 in response to the data input enable signal en_dinds. The core region 40 stores the data transferred by the data input buffer unit 60 in response to the write operation signal wtp6.

Herein, although the command decoder 30 decodes not only a write command but also other commands, e.g., a read command and a precharge command, it is assumed that the command decoder 30 decodes only command signals related to a write operation.

FIG. 2 is a schematic circuit diagram depicting the command input buffer unit 10 and the command delay unit 20 shown in FIG. 1.

As shown, the command input buffer unit 10 includes a first to a fourth command input buffer 11 to 14 for respectively buffering the chip selection bar signal csb, the row address strobe bar signal rasb, the column address strobe bar signal casb and the write enable bar signal web. Each command input buffer also receives a clock enable signal cke and a reference signal vref.

The command delay unit 20 includes a first to a fourth command delays 21 to 24 for respectively delaying each output of the first to the fourth command input buffers 11 to 14 for a predetermined delay time. Herein, the command delay unit 20 is employed for the setup of inputted command signals and for controlling a hold timing.

FIG. 3 is a schematic circuit diagram showing a part of the command decoder 30 shown in FIG. 1 for generating the write operation signal wtp6.

As shown, the command decoder 30 receives command signals outputted from the first to the fourth delays 21 to 24, i.e., cs3, ras2b, cas3 and we3, to thereby generate the write operation signal wtp6 in response to an internal clock signal clkp4. The write operation signal wtp6 has a form of a high level pulse.

FIG. 4 is a schematic circuit diagram showing the data input enable control unit 50 shown in FIG. 1.

As shown, the data input enable control unit 50 activates the data input enable signal en_dinds as a logic high level when the write operation signal wtp6 is inputted as a high level pulse.

Herein, the internal clock signal clkp4 and control signals yburst and wt6rd5b control the data input enable signal en_dinds to be inactivated.

A power-up signal pwrup is activated when a power supply voltage has a stable voltage level so that the data input enable signal en_dinds can be activated after a stabilization of a power supply.

FIG. 5 is a schematic circuit diagram showing a command input buffer, particularly the first command input buffer 11 shown in FIG. 2.

As shown, the first command input buffer 11 is enabled in response to the clock enable signal cke in order to buffer the chip selection bar signal csb according to the reference signal vref and output the buffered signal.

Herein, each command input buffer not only performs the buffering operation but also performs a transformation operation for transforming a voltage level of an externally inputted command to a voltage level used in the semiconductor memory device.

FIG. 6 is a schematic circuit diagram showing a command delay, particularly the first command delay 21 shown in FIG. 2.

As shown, the first command delay 21 includes a first to a sixth capacitors C1 to C6 and a first to a sixth inverters 118 to 123 for delaying a signal inputted to an input node sh and outputting the delayed signal to an output node shd.

A delay amount of the first command delay 21 is controlled by each switch coupled to each capacitor.

FIG. 7 is a schematic circuit diagram showing an improved version of the data input enable control unit 50 shown in FIG. 4.

The improved version of the data input enable control unit 50 is designed for use in a semiconductor memory device which performs a data access operation at a high speed. The improved version of the data input enable control unit 50 can select one of two operations: the two operations includes a first operation of activating the data input enable signal en_dinds according to the write operation signal wtp6 and a second operation of activating the data input enable signal en_dinds according to an active signal rasidle during an active condition and temporarily inactivating the data input signal en_dinds during a read operation.

The selection between the first and the second operations is determined by a CAS latency (CL). Herein, in case that the CL is 4 or 5, the second operation is selected.

FIG. 8 is a wave diagram showing an operation of the conventional semiconductor memory device.

Referring to FIGS. 1 to 8, the operation of the conventional semiconductor memory device is described below.

When command signals for a write command are inputted, the command input buffer unit 10 adjusts of a signal level of the inputted command signals to an internal signal level and outputs the adjusted command signals to the command delay unit 20. The command delay unit 20 delays an output of the command input buffer unit 10 for controlling the hold timing and for the setup of the command signals.

The command decoder 30 decodes the command signals outputted from the command delay unit 20 to thereby generate the write operation signal wtp6 synchronized with the internal clock signal clkp4 after detecting a write command.

Then, the data input enable control unit 50 activates the data input enable signal en_dinds as a logic high level in response to the write operation signal wtp6. The data input buffer unit 60 inputs data to the core region 40 in response to a high level of the data input enable signal en_dinds.

Thereafter, the core region 40 stores the data inputted by the data input buffer unit 40.

Therefore, the data input buffer unit 60 is not always enabled, i.e., the data input buffer unit 60 is enabled only when the data is inputted to be written to thereby reduce a power consumption. Since there is about one clock cycle between a timing of inputting a write command and a timing of inputting the data, the power saving operation of the data input buffer unit 60 is possible.

The data input enable signal en_dinds is activated in response to the write operation signal wtp6 and is inactivated after clocks of a burst length are passed and, thus, during an activation period of the data input enable signal en_dinds, the data input buffer unit 60 is enabled to input data.

However, the data input enable signal en_dinds is activated, regardless of a timing of an external clock signal, after a predetermined time is passed since command signals for a write command are inputted. Herein, when a semiconductor memory device is operated at a low frequency, there is an enough time for activating the data input enable signal en_dinds after the command signals for a write command are inputted; however, when a semiconductor memory device is operated at a high frequency, the enough time margin for activating the data input enable signal en_dinds is not secured.

That is, since there is a time margin of only one clock cycle for activating the data input enable signal en_dinds, the enough time margin for activating the data input enable signal en_dinds cannot be secured at the high operational frequency.

Therefore, in case of a semiconductor memory device operated at a high frequency, a first data cannot be inputted after the command signals for a write command are inputted.

For solving the above-mentioned problem, the improved version of the data input enable control unit 60 has been developed. In this case, when the CL is 2, 2.5 or 3, the first operation is performed. When the CL is 4 or 5, the second operation is performed.

However, in case of using the improved version of the data input enable control unit 60, the data input buffer unit 60 is almost always enabled and, thus, a power consumption is increased.

### SUMMARY OF INVENTION

It is, therefore, an object of the present invention to provide a semiconductor memory device capable of performing a data access operation at a high speed reducing a power consumption.

In accordance with an aspect of the present invention, there is provided a semiconductor memory device, including: a command input buffer unit for buffering a command signal and for generating a detection signal in response to a write command; a data input enable control unit for generating a data input enable signal in response to the detection signal; a data input buffer unit for transferring a data in response to the data input enable signal; a command decoder for decoding the command signal to thereby generate a decoded signal; and a core region for storing the data transferred by the data input buffer unit in response to the decoded signal.

In accordance with another aspect of the present invention, there is provided a method for operating a synchronous semiconductor memory device which performs a data access operation in synchronization with a clock signal, including the steps of: a) receiving and transferring an operation command configured by a chip selection signal, a RAS signal, a CAS signal and a write enable signal; b) generating a detection signal by detecting a write command from the operation command; c) receiving a data inputted according to the write command in response to the detection signal; d) delaying the transferred signal generated at the step a) for a predetermined delay time for matching a setup/hold timing with the clock signal; and e) decoding the delayed signal generated at the step d) in order to stored the data received at the step c).

### BRIEF DESCRIPTION OF THE DRAWINGS

The above and other objects and features of the present invention will become apparent from the following description of preferred embodiments taken in conjunction with the accompanying drawings, in which:

FIG. 1 is a block diagram showing a conventional semiconductor memory device;

FIG. 2 is a schematic circuit diagram depicting the command input buffer unit and the command delay unit shown in FIG. 1;

FIG. 3 is a schematic circuit diagram showing a part of the command decoder shown in FIG. 1;

FIG. 4 is a schematic circuit diagram showing the data input enable control unit shown in FIG. 1;

FIG. 5 is a schematic circuit diagram showing the first command input buffer shown in FIG. 2;

FIG. 6 is a schematic circuit diagram showing the first command delay shown in FIG. 2;

FIG. 7 is a schematic circuit diagram showing an improved version of the data input enable control unit shown in FIG. 4;

FIG. 8 is a wave diagram showing an operation of the conventional semiconductor memory device shown in FIG. 1;

FIG. 9 is a block diagram showing a semiconductor memory device in accordance with a preferred embodiment of the present invention;

FIG. 10 is a schematic circuit diagram showing the command input buffer unit shown in FIG. 9;

FIG. 11 is a schematic circuit diagram showing the data input enable control unit shown in FIG. 9;

FIG. 12 is a wave diagram showing an operation of the semiconductor memory device shown in FIG. 9; and

FIG. 13 is a schematic circuit diagram showing a modified version of the signal combination unit shown in FIG. 10.

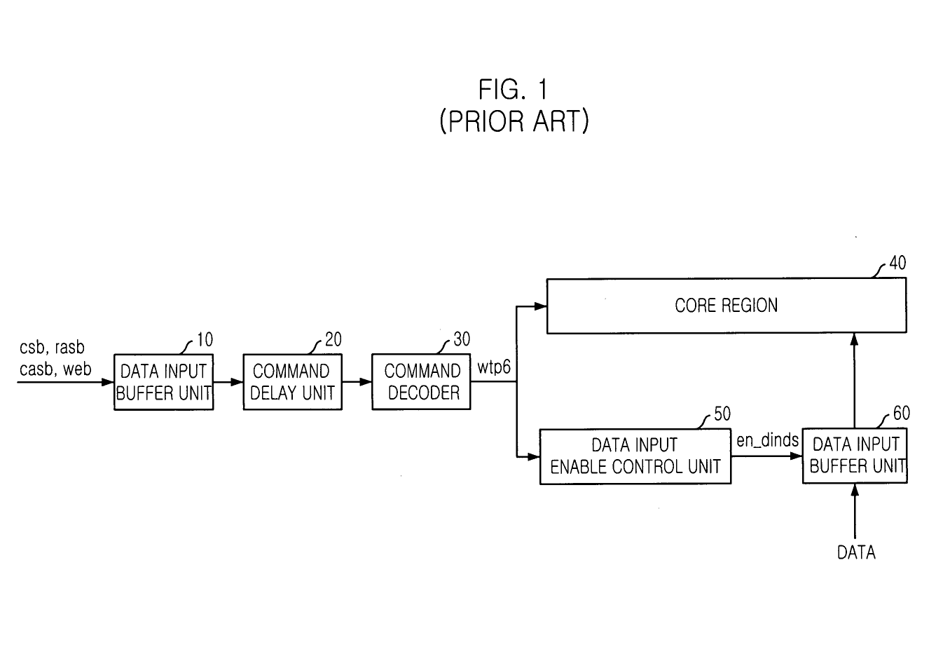

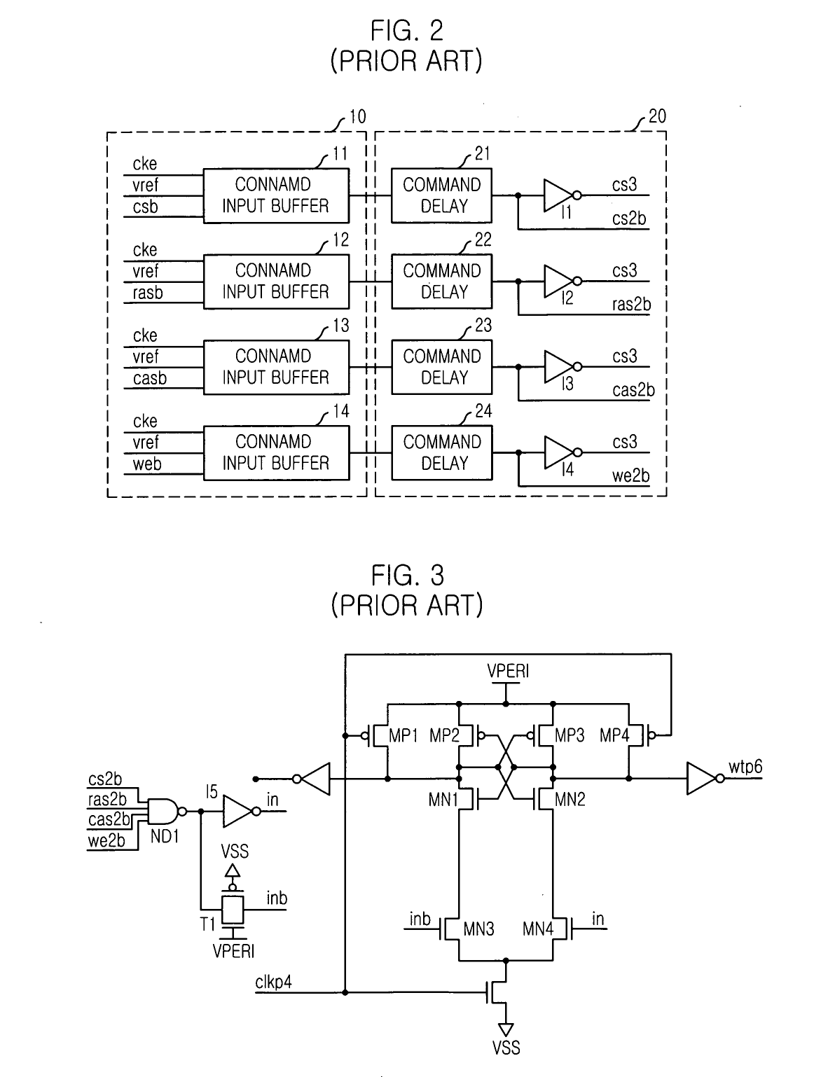

### DETAILED DESCRIPTION OF INVENTION

Hereinafter, a semiconductor memory device in accordance with the present invention will be described in detail referring to the accompanying drawings.

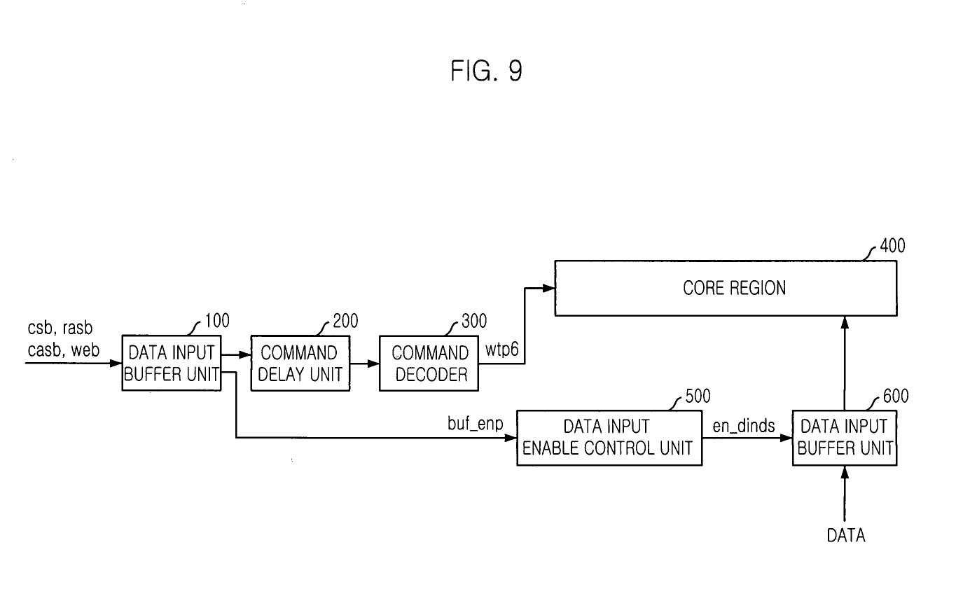

FIG. 9 is a block diagram showing a semiconductor memory device in accordance with a preferred embodiment of the present invention.

As shown, the semiconductor memory device includes a command input buffer unit 100, a command decoder 300, a core region 400, a data input enable control unit 500 and a data input buffer unit 600.

The command input buffer unit 100 buffers a plurality of command signals, i.e., a chip selection bar signal csb, a row address strobe bar signal rasb, a column address strobe bar signal casb and a write enable bar signal web. The command input buffer unit 100 also generates a detection signal buf_enp in response to a write command.

The data input enable control unit 500 generates a data input enable signal en_dinds in response to the detection signal buf_enp. The data input buffer unit 600 transfers a data to the core region 400 in response to the data input enable signal en_dinds.

The command decoder 300 decodes the command signals transferred from the command input buffer unit 100. The core region 400 stores the data transferred by the data input buffer unit 60 in response to a decoded signal outputted from the command decoder 300.

The semiconductor memory device further includes a delay unit 200 connected between the command input buffer unit 100 and the command decoder 300 for delaying the buffered command signals outputted from the command input buffer unit 100 to thereby match a setup/hold timing with a clock signal.

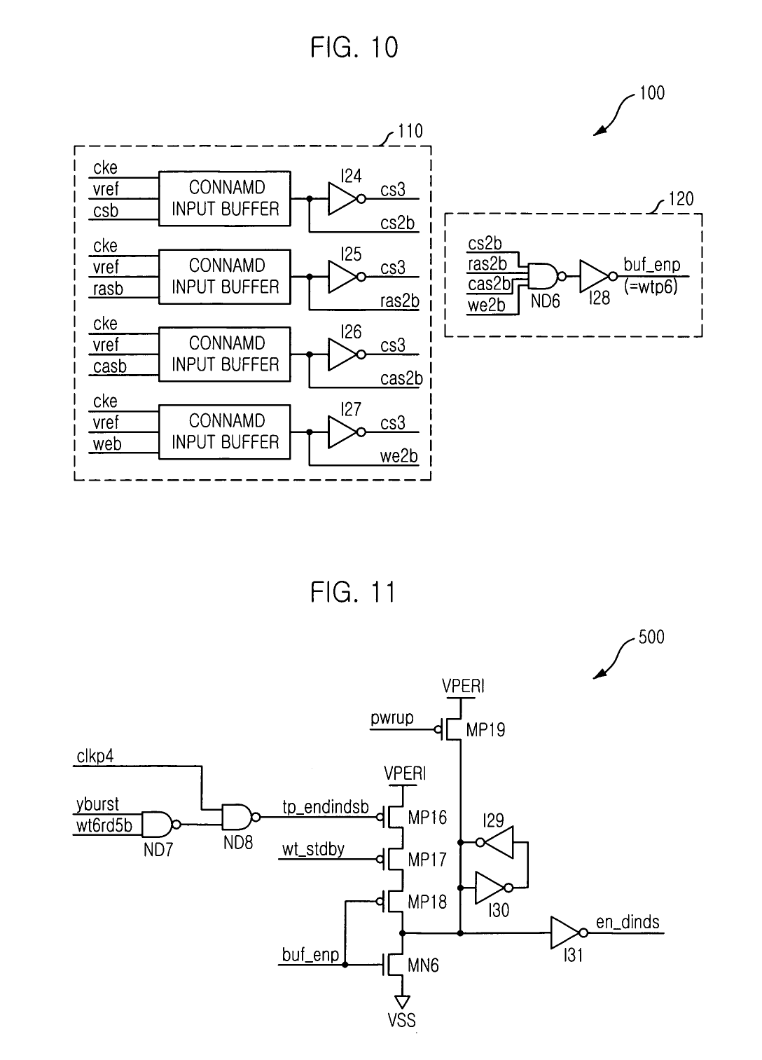

FIG. 10 is a schematic circuit diagram showing the command input buffer unit 100 shown in FIG. 9.

As shown, the command input buffer unit 100 includes a buffer unit 110 having four command input buffers for respectively buffering the chip selection bar signal csb, the row address strobe bar signal rasb, the column address strobe bar signal casb and the write enable bar signal web. The command input buffer unit 100 further includes a signal combination unit 120 for combining signals outputted from the buffer unit 110 to thereby generate the detection signal buf_enp by detecting the write command.

Herein, each command input buffer is activated in response to a clock enable signal cke and receives one of the plurality of command signals in response to a reference voltage vref. The buffer unit 110 generates not only the buffered command signals but also inverted version of the buffered command signals, i.e., cs3, ras3, cas3 and we3.

The signal combination unit 120 includes a first NAND gate ND6 for receiving an inverted chip selection bar signal cs3, a buffered row address strobe signal ras2b, an inverted column address strobe bar signal cas3 and an inverted write enable bar signal we3; and a first inverter 128 for inverting an output of the first NAND gate ND6 to thereby generate the detection signal buf_enp.

FIG. 11 is a schematic circuit diagram showing the data input enable control unit 500 shown in FIG. 9.

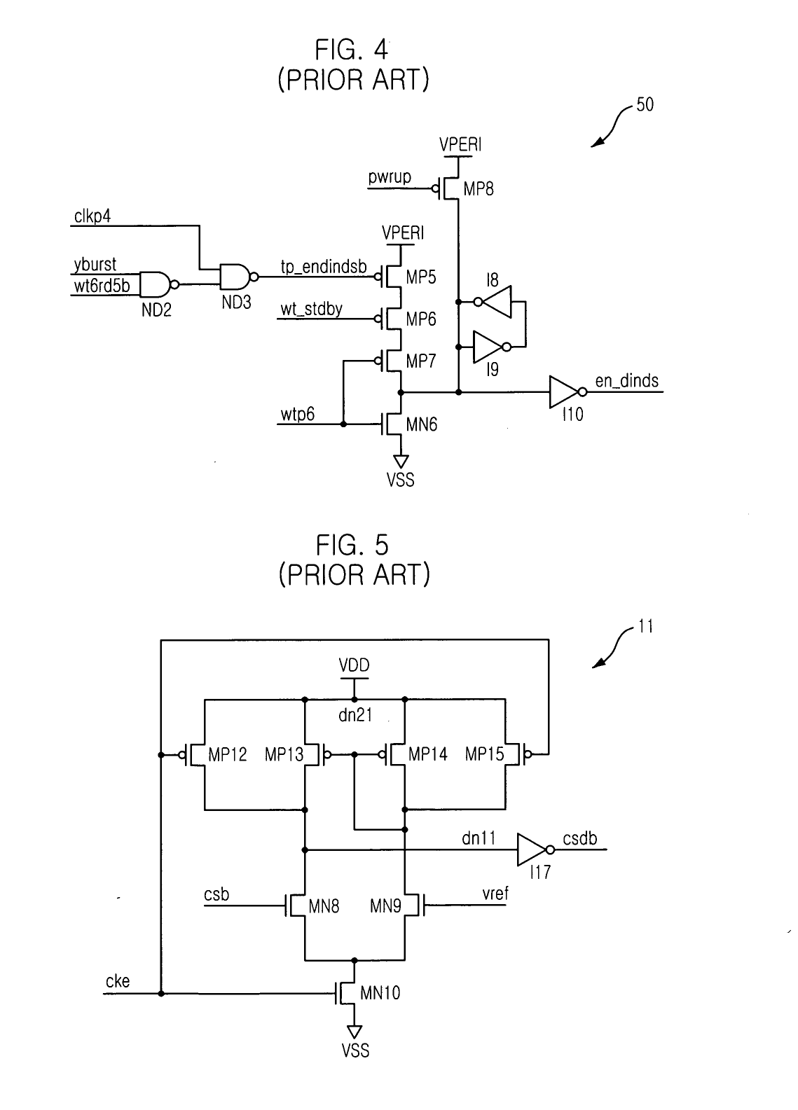

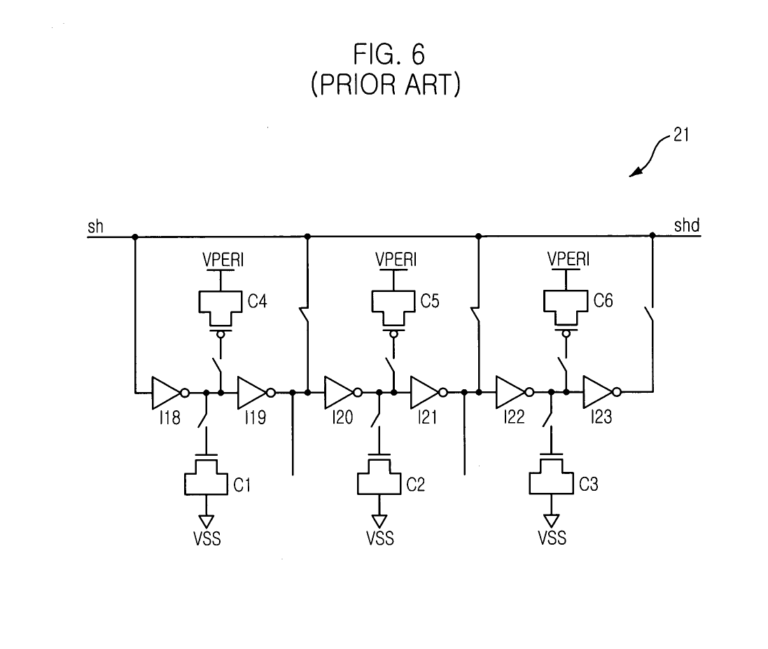

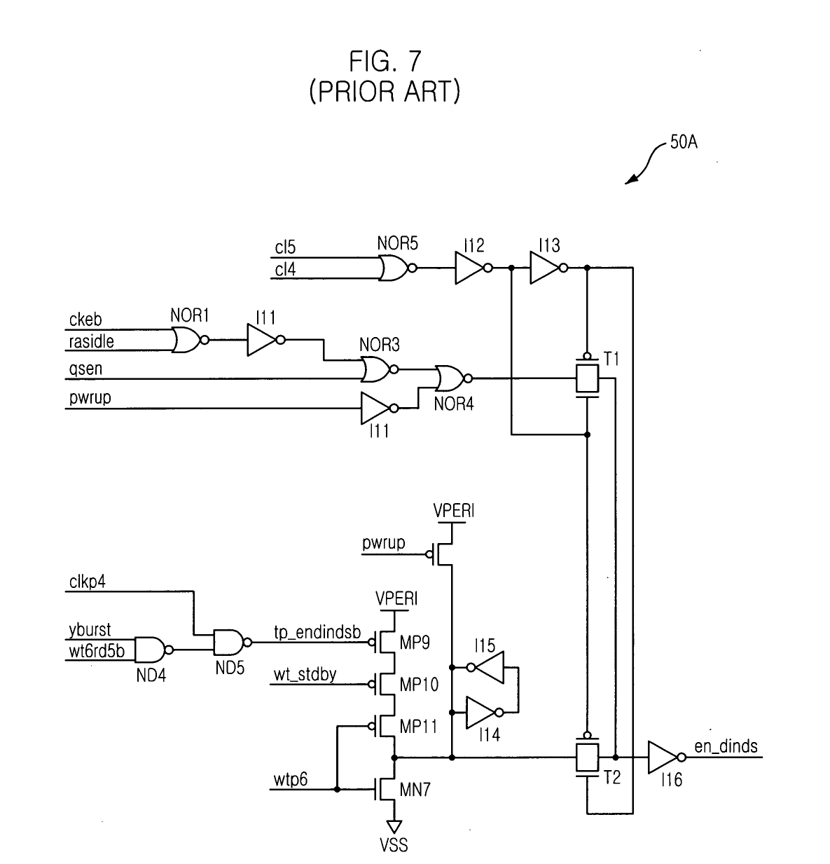

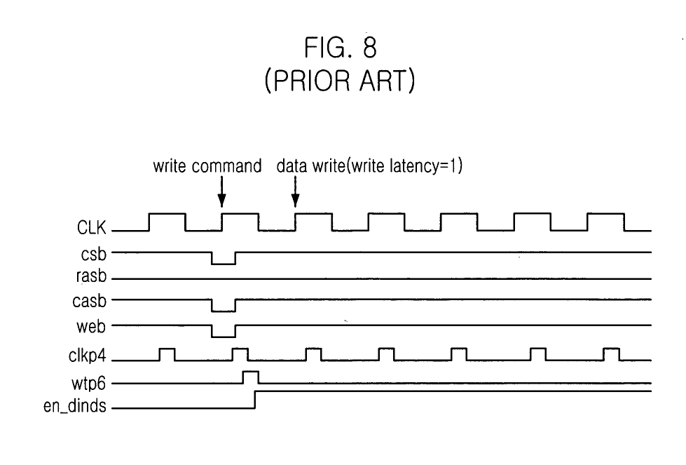

A structure of the data input enable control unit 500 is similar to that of the data input enable control unit 50 shown in FIG. 4. However, unlike the data input enable control unit 50 shown in FIG. 4, the data input enable control unit 500 receives the detection signal buf_enp instead of a write operation signal wtp6 generated by the command decoder 300 in order to activate the data input enable signal en_dinds.

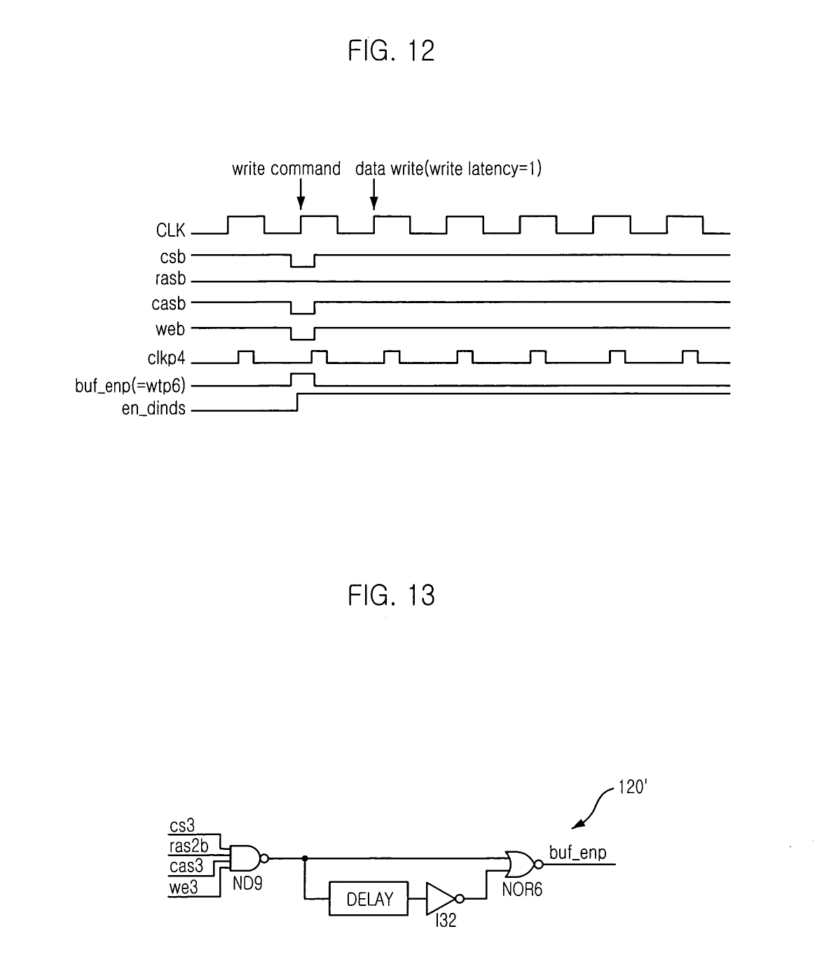

FIG. 12 is a wave diagram showing an operation of the semiconductor memory device shown in FIG. 9.

Referring to FIGS. 9 to 12, the operation of the semiconductor memory device is described below.

The command input buffer unit 100 buffers the plurality of command signals and transfers the buffered signals to the command delay unit 200. The command input buffer unit 100 also activates the detection signal buf_enp when command signals for the write command are inputted. The data input enable control unit 500 activates the data input enable signal en_dinds in response to the detection signal buf_enp.

The data input buffer unit 600 receives data corresponding to the write command and inputs the received data to the core region 400 in response to the data input enable signal en_dinds.

Meanwhile, the delay unit 200 delays the buffered signals outputted from the command input buffer unit 100 to thereby match the setup/hold timing with the clock signal. Herein, the clock signal is a reference clock for the semiconductor memory device to perform a data access operation.

Thereafter, the command decoder 300 decodes outputs of the command delay unit 200 and transfers the decoded signal to the core region 400. Herein, the command decoder 300 generates the write operation signal wtp6 by decoding the write command.

The core region 400 stores the data inputted by the data input buffer unit 600 into a corresponding cell in response to the write operation signal wtp6.

As above-mentioned, in accordance with the present invention, a data is inputted by a data input buffer unit in direct response to the command signals inputted for the write command, and the inputted data is stored into the corresponding cell in response to a decoded signal generated by a command decoder.

Accordingly, even though an operational frequency is increased, a time margin for inputting data to be written can be secured and, thus, the data can be stably stored.

However, the conventional semiconductor memory device always enables a data input unit not using the command signals and, then, disables the data input unit for a predetermined time by using a CAS latency at a high operational frequency. Accordingly, a power consumption is increased. On the contrary, in accordance with the present invention, a data input operation can be controlled by using the write command at a high operational frequency and, thus, the data input unit can be efficiently enabled. Therefore, a power consumption is relatively decreased.

FIG. 12 shows the above-mentioned process for inputting data. As shown, the detection signal buf_enp is generated in response to the plurality of command signals, i.e., csb, rasb, casb and web, and, then, the data input enable signal en_dinds is generated in response to the detection signal buf_enp.

FIG. 13 is a schematic circuit diagram showing a modified version of the signal combination unit 120 shown in FIG. 10.

As shown, the modified signal combination unit 120′ includes a second NAND gate ND9 for receiving the inverted chip selection bar signal cs3, the buffered row address strobe signal ras2b, the inverted column address strobe bar signal cas3 and the inverted write enable bar signal we3; a delay for delaying an output of the second NAND gate ND9; a second inverter I32 for inverting an output of the delay; a NOR gate NOR6 for generating the detection signal buf_enp by performing a logic NOR operation to the output of the second NAND gate ND9 and an output of the second inverter I32.

Since an operation of the modified signal combination unit 120′ is same to that of the signal combination unit 120 except that the detection signal buf_enp is generated as a pulse signal, a detailed description of the modified signal combination unit 120′ is omitted.

As above-mentioned, the time margin for inputting data to be written is increased and, thus, the data can be stably stored even at a high operational frequency. Further, since the data input timing can be controlled by the write command even at a high operational frequency, the data input unit can be efficiently operated and, thus, a power consumption can be reduced.

The present application contains subject matter related to Korean patent application No. 2005-58715, filed in the Korean Patent Office on Jun. 30, 2005, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. A semiconductor memory device, comprising:
a command input buffer unit for buffering command signals and generating a detection signal in response to a write command;
a data input enable control unit for generating a data input enable signal in response to the detection signal;
a data input buffer unit for transferring a data in response to the data input enable signal;
a command decoder for decoding the command signal to thereby generate a decoded signal; and
a core region for storing the data transferred by the data input buffer unit in response to the decoded signal.

2. The semiconductor memory device as recited in claim 1, further comprising a command delay unit connected between the command input buffer unit and the command decoder for delaying buffered command signals outputted from the command input buffer unit to thereby match a setup/hold timing with a clock signal.

3. The semiconductor memory device as recited in claim 1, wherein the command input buffer unit includes:
a first command input buffer for buffering a chip selection signal;
a second command input buffer for buffering a row address strobe (RAS) signal;
a third command input buffer for buffering a column address strobe (CAS) signal;
a fourth command input buffer for buffering a write enable signal; and
a signal combination unit for generating the detection signal by detecting the write command based on outputs of the first to the fourth command input buffers.

4. The semiconductor memory device as recited in claim 3, wherein the signal combination unit includes:
a NAND gate for receiving an inverted chip selection signal, the RAS signal, an inverted CAS signal and an inverted write enable signal; and
an inverter for generating the detection signal by inverting an output of the NAND gate.

5. The semiconductor memory device as recited in claim 3, wherein the signal combination unit includes:
a NAND gate for receiving an inverted chip selection signal, the RAS signal, an inverted CAS signal and an inverted write enable signal;
a delay for delaying an output of the NAND gate for a predetermined delay time;
an inverter for inverting an output of the delay; and
a NOR gate for generating the detection signal by performing a logic NOR operation to the output of the NAND gate and an output of the inverter.

6. A method for operating a synchronous semiconductor memory device which performs a data access operation in synchronization with a clock signal, comprising the steps of:
a) receiving and transferring an operation command configured by a chip selection signal, a RAS signal, a CAS signal and a write enable signal;
b) generating a detection signal by detecting a write command from the operation command;
c) receiving a data inputted according to the write command in response to the detection signal;
d) delaying the transferred signal generated at the step a) for a predetermined delay time for matching a setup/hold timing with the clock signal; and
e) decoding the delayed signal generated at the step d) in order to stored the data received at the step c).
